(19) United States
(12) Patent Application Publication
(10) Pub. No.: US 2012/0009796 A1
(43) Pub. Date: Jan. 12, 2012

(54) POST-ASH SIDEWALL HEALING

(75) Inventors: Zhenjiang Cui, San Jose, CA (US); Anchuan Wang, San Jose, CA (US); Mehul Naik, San Jose, CA (US); Nitin Ingle, San Jose, CA (US); Young Lee, San Jose, CA (US); Shankar Venkataraman, San Jose, CA (US)

(73) Assignee: Applied Materials, Inc., Santa Clara, CA (US)

(21) Appl. No.: 12/909,167

(22) Filed: Oct. 21, 2010

Related U.S. Application Data
(60) Provisional application No. 61/362,776, filed on Jul. 9, 2010.

(51) Int. Cl. H01L 21/3065

(52) U.S. Cl. 438/711; 257/E21.218

(57) ABSTRACT

Methods of decreasing the effective dielectric constant present between two conducting components of an integrated circuit are described. The methods involve the use of a gas phase etch which is selective towards the oxygen-rich portion of the low-K dielectric layer. The etch rate attenuates as the etch process passes through the relatively high-K oxygen-rich portion and reaches the low-K portion. The etch process may be easily timed since the gas phase etch process does not readily remove the desirable low-K portion.

### CROSS-REFERENCES TO RELATED APPLICATIONS

This application claims the benefit of U.S. Prov. Pat. App. No. 61/362,776 filed Jul. 9, 2010, and titled “POST-ASH SIDEWALL HEALING,” which is incorporated herein by reference in its entirety for all purposes.

### BACKGROUND OF THE INVENTION

Integrated circuit fabrication methods have reached a point where many hundreds of millions of transistors are routinely formed on a single chip. Each new generation of fabrication techniques and equipment are allowing commercial scale fabrication of ever smaller and faster transistors, but also increase the difficulty to make even smaller, faster circuit elements. The shrinking dimensions of circuit elements, now well below the 50 nm threshold, has caused chip designers to look for new low-resistivity conductive materials and new low-dielectric constant (i.e., low-k) insulating materials to improve (or simply maintain) the electrical performance of the integrated circuit.

Parasitic capacitance becomes a significant impediment to transistor switching rate as the number of transistors per area is increased. Capacitance exists between all adjacent electrically isolated conductors within an integrated circuit and may limit the switching rate regardless of whether the conducting portions are at the “front end” or the “back end” of the manufacturing process flow.

Thus, there is a need for new techniques and materials to form low-k material between adjacent conductors. One class of materials used to provide low-K separation between conductors is oxidized organo-silane films, such as the Black Diamond™ films commercially available from Applied Materials, Inc. of Santa Clara, Calif. These films have lower dielectric constants (e.g., about 3.5 or less) than conventional spacer materials like silicon oxides and nitrides. Unfortunately, some new processes involve exposing low-K films to environments which can increase the effective dielectric constant and limit device performance.

Thus there is a need for new processes which maintain a lower effective dielectric constant following exposure of a low-K film to these environments.

### BRIEF SUMMARY OF THE INVENTION

Methods of decreasing the effective dielectric constant present between two conducting components of an integrated circuit are described. The methods involve the use of a gas phase etch which is selective towards the oxygen-rich portion of the low-K dielectric layer. The etch rate attenuates as the etch process passes through the relatively high-K oxygen-rich portion and reaches the low-K portion. The etch process may be easily timed since the gas phase etch process does not readily remove the desirable low-K portion.

Embodiments of the invention include methods of decreasing the effective dielectric constant of a low-K dielectric material between two trenches on a patterned substrate in a substrate processing region. The low-K dielectric material forms walls of the two trenches. The method includes transferring the patterned substrate into the substrate processing region. The method further includes gas phase etching the patterned substrate to decrease the average dielectric constant of the low-K dielectric material by removing an outer dielectric layer from the low-K dielectric material.

Additional embodiments and features are set forth in part in the description that follows, and in part will become apparent to those skilled in the art upon examination of the specification or may be learned by the practice of the disclosed embodiments. The features and advantages of the disclosed embodiments may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIGS. 1A-1B are cross-sectional views of gaps during treatment according to disclosed embodiments.

FIG. 2 is a flow chart of a gapfill photoresist removal process according to disclosed embodiments.

FIG. 3 is a cross-sectional view of a processing chamber according to disclosed embodiments.

FIG. 4 is a processing system according to disclosed embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

Methods of decreasing the effective dielectric constant present between two conducting components of an integrated circuit are described. The methods involve the use of a gas phase etch which is selective towards the oxygen-rich portion of the low-K dielectric layer. The etch rate attenuates as the etch process passes through the relatively high-K oxygen-rich portion and reaches the low-K portion. The etch process may be easily timed since the gas phase etch process does not readily remove the desirable low-K portion. Gas phase etches are preferable to liquid buffered oxide etches especially for processing patterned substrates. Gas phase etchants are more easily removed from confined structures than liquid etchants.

Embodiments of the invention are directed to methods of etching a low-K material on a patterned substrate to increase the effective dielectric constant thereby improving device performance. An exemplary process flow which benefits from methods presented herein involves two distinct litho-etch patterns transferred to a substrate. These processes may be designed to pattern a substrate twice in order to achieve a desirable step in a via structure rather than the traditional via having relatively straight vertical walls. These process sequences may require coating a patterned substrate with photoresist such that photoresist permeates vias and other gaps in a low-K material. Removing the photoresist typically involves ashing, i.e. exposing the structure to an oxidizing precursor. While removing the gapfilling photoresist, the ashing step also changes the sidewalls of the gap in a way that increases the dielectric constant within a thin outer layer of the low-K material. Some ashes involve exposure to oxygen-containing compounds excited in a plasma. In these cases, the oxygen treatment oxidizes the surface of the low-K material and increases the oxygen content relative to the carbon content. The methods presented herein remove this thin layer of relatively higher-K material in order to bring the dielectric constant back down near its pre-ash level.

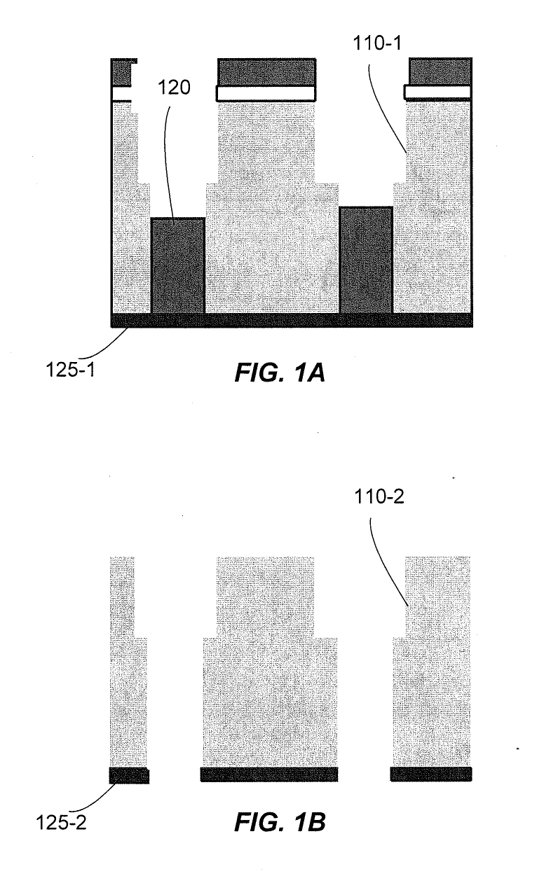

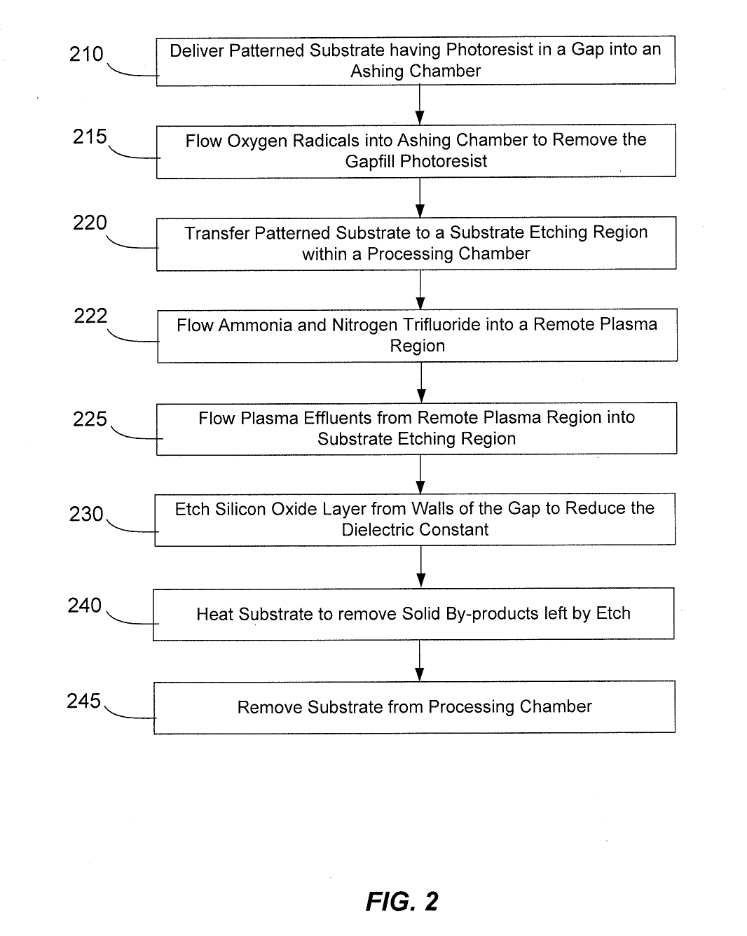

In order to better understand and appreciate the invention, reference is now made to FIGS. 1-2 which are cross-sectional views of gaps during treatment and a flowchart for treating the gaps according to disclosed embodiments. The structure shown in FIG. 1A results from a litho-etch-litho-etch sequence in which the second lithography-etch step opens a wider trench into low dielectric constant material 110-1. The second etch penetrates only part of the way to the bottom of the trench leaving a step in the low-K material 110-1. Above and below the step are substantially vertical walls formed of low-K material. The walls may deviate from the theoretically vertical lines shown in FIGS. 1A-1B but may be within 10°, 5° or 2° of vertical, in disclosed embodiments. Following the second etch, some photoresist 120 remains toward the bottom of the trenches which needs to be removed before the gaps are filled with metal. The process of removing the residual photoresist 120 begins when the patterned substrate is transferred into a processing chamber (operation 210). A flow of oxygen-radicals is conducted into the ashing chamber (operation 215) and removes the photoresist from within the trenches. In the example depicted in FIG. 1A, a silicon carbon-nitride (SiCN) layer 125-1 is included to protect low-K material 110-1 from metallic diffusion from underlying materials. The layer of SiCN 125-1 is also modified by the oxygen-radicals such that the portion of SiCN at the bottom of the trench is removed yielding patterned SiCN layer 125-2. An exemplary SiCN layer is Blok™ which is available from Applied Materials, Santa Clara, Calif. A SiCN layer is present in some embodiments and not in others. The oxygen-radical flow also oxidizes the walls of low-K material 110 undesirably raising the dielectric constant near the surface (the walls of the trenches). An exemplary low-K material material is silicon oxycarbide (SiOC) and an exemplary SiOC product is Black Diamond™, also available from Applied Materials. Ignoring the formation of an oxygen-rich (relatively higher K) surface layer and proceeding with a gapfill deposition of the trenches with metal would limit the operational regime of a completed device.

The reduced dielectric constant low-K material 110 may be restored to nearly its pre-ashing level using the following steps. The patterned substrate is transferred (operation 220) to a substrate etching region of a processing chamber for further processing. Flows of ammonia and nitrogen trifluoride are initiated into a plasma region separate from the processing region (operations 222). The separate plasma region may be referred to as a remote plasma region herein and may be a distinct module from the processing chamber or a compartment within the processing chamber. Remote plasma effluents (products from the remote plasma) are flowed into the processing region and allowed to interact with the substrate surface (operation 225). The flow of plasma effluents react with the surface to produce solid residue which contains material from the plasma effluents and material from the walls of the affected low-K material 110. Detailed chemical reactions which may be useful in understanding this process will be presented in the exemplary equipment section. The solid residue is then removed by heating the patterned substrate above its sublimation point (operation 240). The process is completed by removing the patterned substrate from the substrate etching region (operation 245) and the resulting structure is shown in FIG. 1B.

The etch rate of the outer dielectric layer is greater than the relatively lower-K dielectric material inside the outer dielectric layer. In embodiments of the invention, the gas phase etch rate of the outer dielectric layer exceeds that of the remainder of the low-K dielectric material by a multiplicative factor greater than 25, 50 or 100. The thickness of the outer dielectric layer is less than or about 150 Å, less than or about 100 Å or less than or about 50 Å, in embodiments.

The exemplary process just described is a subset of the family of SiConi™ etches, which generally involve concurrent flows of a fluorine-containing precursor and a hydrogen-containing precursor. Fluorine-containing precursors include nitrogen trifluoride, hydrogen fluoride, diatomic fluorine, monatomic fluorine and fluorine-substituted hydrocarbons or combinations thereof in different embodiments. Hydrogen-containing precursors include atomic hydrogen, diatomic hydrogen, ammonia, hydrocarbons, incompletely halogen-substituted hydrocarbons or combinations thereof in different embodiments. For simplicity, some discussions contained herein may refer to the exemplary SiConi™ etch using the combination of ammonia and nitrogen trifluoride. Any SiConi™ etch may be used in place of the exemplary one described and shown in FIG. 2. All SiConi™ etches which contain fluorine and hydrogen (but little or essentially no oxygen) exhibit a strong selectivity towards etching silicon oxide. These etch processes remove silicon, polysilicon and silicon oxycarbide very slowly. As a consequence, the SiConi™ has the added benefit of leaving the desirable silicon oxycarbide low-K material 110 essentially intact even if the etch is continued after the silicon oxide is consumed from the walls of low-K material 110. This selectivity allows the process to be timed rather than using any other form of end-point determination.

Though the examples described herein pertain to a double patterning (LELE) of a low-K dielectric layer, other process flows are possible which require photoresist to be deposited in a gap within a low-K layer. As a result, the methods presented and claimed have utility in any application involving ashing of any gapfill material which lends itself to removing by an oxidizing treatment. Ashable gapfill materials include bottom or top anti-reflective coatings (BARC or TARC) as well as a variety of photoresists and other similar carbon-containing materials. Ashable gapfill materials are essentially devoid of oxygen, in disclosed embodiments. The oxidizing treatment which removes the ashable gapfill material but undesirably modifies the walls, raising the dielectric constant in the modified surface layer. The raised dielectric constant can be lowered using the methods described herein. The profile of trenches may contain a step structure on the trench wall as shown in FIGS. 1A-1B, but essentially no step is present in other disclosed embodiments.

As described earlier, the gaps and trenches are formed in low-K material. The exemplary gap described possesses a step between two approximately vertical walls in the low-K material (see FIG. 1). In other embodiments, no step is formed and a single approximately vertical wall is formed in the low-K material. The single vertical wall may be within 10°, 5° or 2° of vertical, in disclosed embodiments. Before ashing (or after treatments presented herein) the dielectric constant of the low-K material may be less than 3.9, 3.7, 3.5, 3.3 or 3.1, in disclosed embodiments. The dielectric constant is largely determined by the concentration of carbon within a silicon oxycarbide low-K layer. After ashing, the outer dielectric layer may have a dielectric constant greater than 3.0, 3.2 or 3.5, while the remainder of the low-K dielectric material has a dielectric constant less than 3.0, 3.2 or 3.5, respectively, according to embodiments of the invention.

Optional steps may be used after gas phase etching. The gas phase etching just described may leave post-etch residue containing portions of the gas phase etchants. The presence of the post-etch residue may be linked to electrical leakage between adjacent conducting lines. The leakage may be caused by fluorine-containing post-etch residue, for example. Therefore, the etched substrate may be subsequently treated with plasma effluents from a plasma containing one or more of Ar, N₂, NH₃, and H₂ to remove some of the post-etch residue and mitigate any electrical leakage which would have been present.

Oxygen radicals are used to remove the gapfill photoresist 120 during operation 215. Oxygen radicals are typically formed in a remote plasma region and flowed to the substrate etching region. The oxygen radicals contain neutral species including one or more of atomic oxygen (O) and ozone (O₃), in embodiments. Some ionized species may be present in the etching region, however, ionized species tend to recombine more rapidly than do unionized (neutral) atomic oxygen and unionized ozone. A remote plasma is preferred over a plasma in the etching region, in embodiments, to ensure that ionized species have ample opportunity to neutralize. Apertures and path-lengths from the remote plasma to the etching region are preferably chosen to allow neutral atomic oxygen (O) to travel to the substrate etching region in disclosed embodiments. In some embodiments, SiF₄ is simultaneously flowed along with the oxygen radicals (using either a remote plasma or an etching region plasma) for the purpose of passivating the sidewalls to reduce the oxidation. An oxidized region of low K material may still develop and exhibit increased dielectric constant. Therefore, structures made in this way may still benefit from the methods disclosed herein.

Separate chambers are described above for use in ashing and SiConi™ etching. In an alternative embodiment, these processes are performed in the same chamber in a sequence of processing steps without removing the patterned substrate from the processing chamber.

Additional gas-phase etch process parameters and process details are disclosed in the course of describing an exemplary processing system.

### Exemplary Processing System

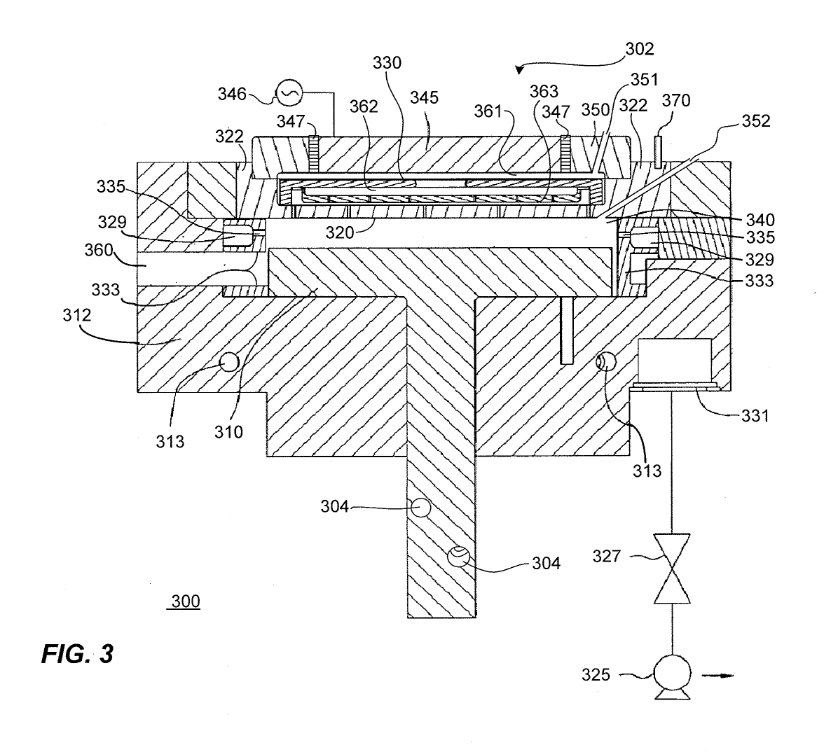

FIG. 3 is a partial cross sectional view showing an illustrative processing chamber 300, in which, embodiments of the invention may be carried out. Generally, ammonia and nitrogen trifluoride may be introduced through one or more apertures 351 into remote plasma region(s) 361-363 and excited by plasma power source 346.

In one embodiment, the processing chamber 300 includes a chamber body 312, a lid assembly 302, and a support assembly 310. The lid assembly 302 is disposed at an upper end of the chamber body 312, and the support assembly 310 is at least partially disposed within the chamber body 312. The processing chamber 300 and the associated hardware are preferably formed from one or more process-compatible materials (e.g. aluminum, stainless steel, etc.).

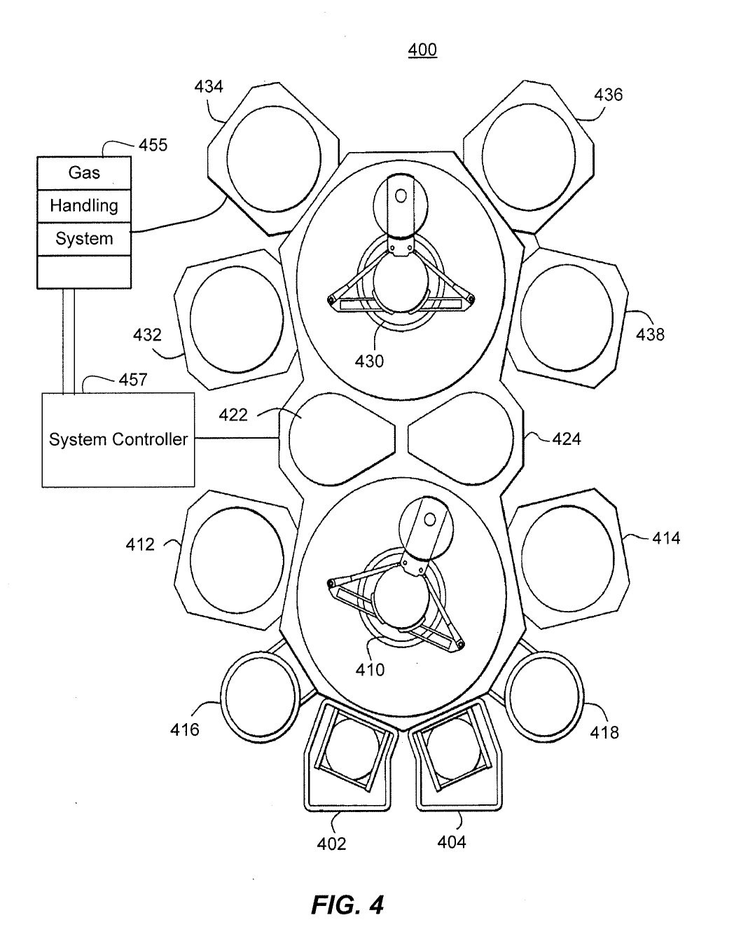

The chamber body 312 includes a slit valve opening 360 formed in a sidewall thereof to provide access to the interior of the processing chamber 300. The slit valve opening 360 is selectively opened and closed to allow access to the interior of the chamber body 312 by a wafer handling robot (not shown). In one embodiment, a wafer can be transported in and out of the processing chamber 300 through the slit valve opening 360 to an adjacent transfer chamber and/or load-lock chamber, or another chamber within a cluster tool. An exemplary cluster tool which may include processing chamber 300 is shown in FIG. 4.

In one or more embodiments, chamber body 312 includes a chamber body channel 313 for flowing a heat transfer fluid through chamber body 312. The heat transfer fluid can be a heating fluid or a coolant and is used to control the temperature of chamber body 312 during processing and substrate transfer. The temperature of the chamber body 312 is important to prevent unwanted condensation of the gas or byproducts on the chamber walls. Exemplary heat transfer fluids include water, ethylene glycol, or a mixture thereof. An exemplary heat transfer fluid may also include nitrogen gas. Support assembly 310 may have a support assembly channel 304 for flowing a heat transfer fluid through support assembly 310 thereby affecting the substrate temperature.

The chamber body 312 can further include a liner 333 that surrounds the support assembly 310. The liner 333 is preferably removable for servicing and cleaning. The liner 333 can be made of a metal such as aluminum, or a ceramic material. However, the liner 333 can be any process compatible material. The liner 333 can be bead blasted to increase the adhesion of any material deposited thereon, thereby preventing flaking of material which results in contamination of the processing chamber 300. In one or more embodiments, the liner 333 includes one or more apertures 335 and a pumping channel 329 formed therein that is in fluid communication with a vacuum system. The apertures 335 provide a flow path for gases into the pumping channel 329, which provides an egress for the gases within the processing chamber 300.

The vacuum system can include a vacuum pump 325 and a throttle valve 327 to regulate flow of gases through the processing chamber 300. The vacuum pump 325 is coupled to a vacuum port 331 disposed on the chamber body 312 and therefore, in fluid communication with the pumping channel 329 formed within the liner 333. The terms “gas” and “gases” are used interchangeably, unless otherwise noted, and refer to one or more reactants, catalysts, carrier, purge, cleaning, combinations thereof, as well as any other fluid introduced into the chamber body 312. The term “precursor” is used to refer to any process gas which takes part in a reaction to either remove or deposit material from a surface.

Apertures 335 allow the pumping channel 329 to be in fluid communication with a processing region 340 within the chamber body 312. The processing region 340 is defined by a lower surface of the lid assembly 302 and an upper surface of the support assembly 310, and is surrounded by the liner 333. The apertures 335 may be uniformly sized and evenly spaced about the liner 333. However, any number, position, size or shape of apertures may be used, and each of those design parameters can vary depending on the desired flow pattern of gas across the substrate receiving surface as is discussed in more detail below. In addition, the size, number and position of the apertures 335 are configured to achieve uniform flow of gases exiting the processing chamber 300. Further, the aperture size and location may be configured to provide rapid or high capacity pumping to facilitate a rapid exhaust of gas from the chamber 300. For example, the number and size of apertures 335 in close proximity to the vacuum port 331 may be smaller than the size of apertures 335 positioned farther away from the vacuum port 331.

A gas supply panel (not shown) is typically used to provide process gas(es) to the processing chamber 300 through one or more apertures 351. The particular gas or gases that are used depend upon the process or processes to be performed within the chamber 300. Illustrative gases can include, but are not limited to one or more precursors, reductants, catalysts, carriers, purge, cleaning, or any mixture or combination thereof. Typically, the one or more gases introduced to the processing chamber 300 flow into plasma volume 361 through aperture(s) 351 in top plate 350. Alternatively or in combination, processing gases may be introduced more directly through aperture(s) 352 into processing region 340. Aperture(s) 352 bypass the remote plasma excitation and are useful for processes involving gases that do not require plasma excitation or processes which do not benefit from additional excitation of the gases. Reactive oxygen created in a remote plasma may be introduced through aperture(s) into processing region 340 without passing through regions 361, 362 and 363. Electronically operated valves and/or flow control mechanisms (not shown) may be used to control the flow of gas from the gas supply into the processing chamber 300. Depending on the process, any number of gases can be delivered to the processing chamber 300, and can be mixed either in the processing chamber 300 or before the gases are delivered to the processing chamber 300.

The lid assembly 302 can further include an electrode 345 to generate a plasma of reactive species within the lid assembly 302. In one embodiment, the electrode 345 is supported by top plate 350 and is electrically isolated therefrom by inserting electrically isolating ring(s) 347 made from aluminum oxide or any other insulating and process compatible material. In one or more embodiments, the electrode 345 is coupled to a power source 346 while the rest of lid assembly 302 is connected to ground. Accordingly, a plasma of one or more process gases can be generated in remote plasma region composed of volumes 361, 362 and/or 363 between electrode 345 and annular mounting flange 322. In embodiments, annular mounting flange comprises or supports gas delivery plate 320. For example, the plasma may be initiated and maintained between electrode 345 and one or both blocker plates of blocker assembly 330. Alternatively, the plasma can be struck and contained between the electrode 345 and gas delivery plate 320, in the absence of blocker assembly 330. In either embodiment, the plasma is well confined or contained within the lid assembly 302. Accordingly, the plasma is a “remote plasma” since no active plasma is in direct contact with the substrate disposed within the chamber body 312. As a result, plasma damage to the substrate may be avoided since the plasma is separated from the substrate surface.

A wide variety of power sources 346 are capable of activating the ammonia and nitrogen trifluoride gases into reactive species. For example, radio frequency (RF), direct current (DC), or microwave (MW) based power discharge techniques may be used. The activation may also be generated by a thermally based technique, a gas breakdown technique, a high intensity light source (e.g., UV energy), or exposure to an x-ray source. Alternatively, a remote activation source may be used, such as a remote plasma generator, to generate a plasma of reactive species which are then delivered into the chamber 300. Exemplary remote plasma generators are available from vendors such as MKS Instruments, Inc. and Advanced Energy Industries, Inc. In the exemplary processing system an RF power supply is coupled to electrode 345. A higher-power microwave power source 346 is beneficial in the event that reactive oxygen will also be produced using power source 346.

The temperatures of the process chamber body 312 and the substrate may each be controlled by flowing a heat transfer medium through chamber body channel 313 and support assembly channel 304, respectively. Support assembly channel 304 may be formed within support assembly 310 to facilitate the transfer of thermal energy. Chamber body 312 and support assembly 310 may be cooled or heated independently. For example, a heating fluid may be flown through one while a cooling fluid is flown through the other.

Other methods may be used to control the substrate temperature. The substrate may be heated by heating the support assembly 310 (or a portion thereof, such as a pedestal) with a resistive heater or by some other means. In another configuration, gas delivery plate 320 may be maintained at a temperature higher than the substrate and the substrate can be elevated in order to raise the substrate temperature. In this case the substrate is heated radiatively or by using a gas to conduct heat from gas delivery plate 320 to the substrate. The substrate may be elevated by raising support assembly 310 or by employing lift pins.

During the etch processes described herein, chamber body 312 may be maintained within an approximate temperature range of between 50° C. and 80° C., between 55° C. and 75° C. or between 60° C. and 70° C. in different embodiments. During exposure to plasma effluents and/or oxidizing agents, the substrate may be maintained below about 100° C., below about 65° C., between about 15° C. and about 50° C. or between about 22° C. and about 40° C. in different embodiments.

Plasma effluents include a variety of molecules, molecular fragments and ionized species. Currently entertained theoretical mechanisms of SiConi™ etching may or may not be entirely correct but plasma effluents are thought to include NH₄F and NH₄F.HF which react readily with low temperature substrates described herein. Plasma effluents may react with a silicon oxide surface to form (NH₄)₂SiF₆, NH₃ and H₂O products. The NH₃ and H₂O are vapors under the processing conditions described herein and may be removed from processing region 340 by vacuum pump 325. A thin continuous or discontinuous layer of (NH₄)₂SiF₆ solid by-products is left behind on the substrate surface.

Following exposure to plasma effluents and the associated accumulation of solid by-products on the vertical walls of trenches (including stepped trenches) as the relatively higher-K thin film is removed from the low-K material, the substrate may be heated to remove the by-products. In embodiments, the gas delivery plate 320 is heatable by incorporating heating element 370 within or near gas delivery plate 320. The substrate may be heated by reducing the distance between the substrate and the heated gas delivery plate. The gas delivery plate 320 may be heated to between about 100° C. and 150° C., between about 110° C. and 140° C. or between about 120° C. and 130° C. in different embodiments. By reducing the separation between the substrate and the heated gas delivery plate, the substrate may be heated to above about 75° C., above about 90° C., above about 100° C. or between about 115° C. and about 150° C. in different embodiments. The heat radiated from gas delivery plate 320 to the substrate should be made sufficient to dissociate or sublimate solid (NH₄)₂SiF₆ on the substrate into volatile SiF₄, NH₃ and HF products which may be pumped away from processing region 340.

Ammonia (or hydrogen-containing precursors in general) may be flowed into remote plasma volume 361 at rates between about 50 sccm and about 300 sccm, between about 75 sccm and about 250 sccm, between about 100 sccm and about 200 sccm or between about 120 sccm and about 170 sccm in different embodiments. Nitrogen trifluoride (or fluorine-containing precursors in general) may be flowed into remote plasma volume 361 at rates between about 25 sccm and about 150 sccm, between about 40 sccm and about 175 sccm, between about 50 sccm and about 100 sccm or between about 60 sccm and about 90 sccm in different embodiments. Combined flow rates of hydrogen-containing and fluorine-containing precursors into the remote plasma region may account for 0.05% to about 20% by volume of the overall gas mixture; the remainder being a carrier gas. In one embodiment, a purge or carrier gas is first initiated into the remote plasma region before those of the reactive gases to stabilize the pressure within the remote plasma region.

Production of the plasma effluents occurs within volumes 361, 362 and/or 363 by applying plasma power to electrode 345 relative to the rest of lid assembly 302. Plasma power can be a variety of frequencies or a combination of multiple frequencies. In the exemplary processing system the plasma is provided by RF power delivered to electrode 345. The RF power may be between about 1 W and about 1000 W, between about 5 W and about 600 W, between about 10 W and about 300 W or between about 20 W and about 100 W in different embodiments. The RF frequency applied in the exemplary processing system may be less than about 200 kHz, less than about 150 kHz, less than about 120 kHz or between about 50 kHz and about 90 kHz in different embodiments.

During an ashing process, reactive oxygen may be formed outside the processing chamber or in the same chambers (361-362) used to excite the etchant gases. Reactive oxygen may contain atomic oxygen (O) and ozone (O₃) flowed along with more stable molecular oxygen (O₂), in embodiments, and the combination will be referred to herein as reactive oxygen. The flow rate of the reactive oxygen may be between about 1 slm and about 50 slm, between about 2 slm and about 30 slm or between about 5 slm and about 10 slm in different embodiments. The flow of the reactive oxygen may be combined with an additional flow of a relatively inert gas (e.g. He, Ar) prior to entering the processing region 340 through aperture(s) 352. The relatively inert carrier gas may be included for a variety of benefits including an increase in the plasma density.

Processing region 340 can be maintained at a variety of pressures during the flow of ozone, oxygen, carrier gases and/or plasma effluents into processing region 340. The pressure may be maintained between about 500 mTorr and about 30 Torr, between about 1 Torr and about 10 Torr or between about 3 Torr and about 6 Torr in different embodiments. Lower pressures may also be used within processing region 340. The pressure may be maintained below or about 500 mTorr, below or about 250 mTorr, below or about 100 mTorr, below or about 50 mTorr or below or about 20 mTorr in different embodiments.

In one or more embodiments, the processing chamber 300 can be integrated into a variety of multi-processing platforms, including the Producer™ GT, Centura™ AP and Endura™ platforms available from Applied Materials, Inc. located in Santa Clara, Calif. Such a processing platform is capable of performing several processing operations without breaking vacuum.

FIG. 4 is a schematic top-view diagram of an illustrative multi-chamber processing system 400. The system 400 can include one or more load lock chambers 402, 404 for transferring of substrates into and out of the system 400. Typically, since the system 400 is under vacuum, the load lock chambers 402, 404 may “pump down” the substrates introduced into the system 400. A first robot 410 may transfer the substrates between the load lock chambers 402, 404, and a first set of one or more substrate processing chambers 412, 414, 416, 418 (four are shown). Each processing chamber 412, 414, 416, 418, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation and other substrate processes.

The first robot 410 can also transfer substrates to/from one or more transfer chambers 422, 424. The transfer chambers 422, 424 can be used to maintain ultrahigh vacuum conditions while allowing substrates to be transferred within the system 400. A second robot 430 can transfer the substrates between the transfer chambers 422, 424 and a second set of one or more processing chambers 432, 434, 436, 438. Similar to processing chambers 412, 414, 416, 418, the processing chambers 432, 434, 436, 438 can be outfitted to perform a variety of substrate processing operations including the dry etch processes described herein in addition to cyclical layer deposition (CLD), atomic layer deposition (ALD), chemical vapor deposition (CVD), physical vapor deposition (PVD), etch, pre-clean, degas, and orientation, for example. Any of the substrate processing chambers 412, 414, 416, 418, 432, 434, 436, 438 may be removed from the system 400 if not necessary for a particular process to be performed by the system 400. Gases may be provided, routed and mixed by gas handling system 455 prior to delivery to exemplary processing chamber.

System controller 457 is used to control motors, valves, flow controllers, power supplies and other functions required to carry out process recipes described herein. System controller 457 may rely on feedback from optical sensors to determine and adjust the position of movable mechanical assemblies. Mechanical assemblies may include the robot, throttle valves and susceptors which are moved by motors under the control of system controller 457.

In an exemplary embodiment, system controller 457 includes a hard disk drive (memory), USB ports, a floppy disk drive and a processor. System controller 457 includes analog and digital input/output boards, interface boards and stepper motor controller boards. Various parts of multi-chamber processing system 400 which contains processing chamber 300 are controlled by system controller 457. The system controller executes system control software in the form of a computer program stored on computer-readable medium such as a hard disk, a floppy disk or a flash memory thumb drive. Other types of memory can also be used. The computer program includes sets of instructions that dictate the timing, mixture of gases, chamber pressure, chamber temperature, RF power levels, susceptor position, and other parameters of a particular process.

A process for depositing a film on a substrate or a process for cleaning chamber 15 can be implemented using a computer program product that is executed by the controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller may be via a touch-sensitive monitor and may also include a mouse and keyboard. In one embodiment two monitors are used, one mounted in the clean room wall for the operators and the other behind the wall for the service technicians. The two monitors may simultaneously display the same information, in which case only one is configured to accept input at a time. To select a particular screen or function, the operator touches a designated area on the display screen with a finger or the mouse. The touched area changes its highlighted color, or a new menu or screen is displayed, confirming the operator's selection.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” is used as a shorthand for and interchangeably with a silicon-and-oxygen-containing material. As such, silicon oxide may include concentrations of other elemental constituents such as nitrogen, hydrogen, carbon and the like. In some embodiments, silicon oxide consists essentially of silicon and oxygen. A gas in an “excited state” describes a gas wherein at least some of the gas molecules are in vibrationally-excited, dissociated and/or ionized states. A gas may be a combination of two or more gases. The terms “trench” and “gap” are used throughout with no implication that the etched geometry has a large horizontal aspect ratio. Viewed from above the surface, trenches and gaps may appear circular, oval, polygonal, rectangular, or a variety of other shapes. The term “via” is used to refer to a low horizontal aspect ratio trench (as viewed from above) which may or may not be filled with metal to form a vertical electrical connection.

Having disclosed several embodiments, it will be recognized by those of skill in the art that various modifications, alternative constructions, and equivalents may be used without departing from the spirit of the disclosed embodiments. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of decreasing the effective dielectric constant of a low-K dielectric material between two trenches on a patterned substrate in a substrate processing region, wherein the low-K dielectric material forms walls of the two trenches, the method comprising:
transferring the patterned substrate into the substrate processing region; and
gas phase etching the patterned substrate to decrease the average dielectric constant of the low-K dielectric material by removing an outer dielectric layer from the low-K dielectric material.

2. The method of claim 1 wherein the gas phase etching comprises:
flowing a fluorine-containing precursor and a hydrogen-containing precursor into a first remote plasma region fluidly coupled to the substrate processing region while forming a plasma in the first remote plasma region to produce plasma effluents;
etching the patterned substrate by flowing the plasma effluents into the substrate processing region while forming solid by-products on the surface of the substrate; and
sublimating the solid by-products by increasing a temperature of the substrate above a sublimation temperature of the solid by-products.

3. The method of claim 2 wherein the fluorine-containing precursor comprises at least one precursor selected from the group consisting of nitrogen trifluoride, hydrogen fluoride, diatomic fluorine, monatomic fluorine and fluorine-substituted hydrocarbons.

4. The method of claim 2 wherein the hydrogen-containing precursor comprises at least one precursor selected from the group consisting of atomic hydrogen, molecular hydrogen, ammonia, a hydrocarbon and an incompletely halogen-substituted hydrocarbon.

5. The method of claim 2 wherein a temperature of the substrate is raised to greater than or about 100° C. during the operation of sublimating the solid by-products.

6. The method of claim 1 wherein the outer dielectric layer has a dielectric constant greater than 3.0 and the remainder of the low-K dielectric material has a dielectric constant less than 3.0.

7. The method of claim 1 wherein the relatively high dielectric constant of the outer dielectric layer is caused by plasma ashing.

8. The method of claim 1 further comprising an operation of ashing the patterned substrate prior to the operation of gas phase etching.

9. The method of claim 1 wherein the outer dielectric layer is removed from the walls of the two trenches.

10. The method of claim 8 wherein the operation of ashing the patterned substrate occurs after the operation of transferring the patterned substrate into the substrate processing region.

11. The method of claim 8 wherein the operation of plasma ashing the patterned substrate occurs before the operation of transferring the patterned substrate into the substrate processing region.

12. The method of claim 1 wherein the thickness of the outer dielectric layer is less than or about 150 Å.

13. The method of claim 1 wherein the etch rate of the outer dielectric layer during gas phase etching exceeds that of the remainder of the low-K dielectric material by a multiplicative factor greater than 50.

14. The method of claim 1 wherein the operation of gas-phase etching the patterned substrate is followed by plasma treating the patterned substrate in an atmosphere containing at least one of argon, nitrogen (N₂), ammonia (NH₃) or hydrogen (H₂) to remove post-etch residue.

15. The method of claim 14 wherein the post-etch residue contains fluorine.
